(19) United States
(12) Patent Application Publication
(10) Pub. No.: US 2025/0300649 A1
(43) Pub. Date: Sep. 25, 2025

(54) HYBRID COMPARATOR CIRCUIT DEVICE

(71) Applicant: KOREA UNIVERSITY RESEARCH AND BUSINESS FOUNDATION, Seoul (KR)

(72) Inventors: Hyung-Min LEE, Seoul (KR); Hyun-Su LEE, Seoul (KR)

(21) Appl. No.: 19/039,548

(22) Filed: Jan. 28, 2025

(30) Foreign Application Priority Data
Mar. 19, 2024 (KR) 10-2024-0037826

(51) Int. Cl. H03K 5/24; H02M 1/00

(52) U.S. Cl. CPC H03K 5/2481; H02M 1/0032

(57) ABSTRACT

Disclosed is a hybrid comparator circuit device. The hybrid comparator circuit device includes: a first mode operation circuit unit detecting a first point where a first reference signal V_{REG} is the same as a low AC input signal by receiving the low AC input signal V_{INN}; a second mode operation circuit unit detecting a second point where a second reference signal V_{REG} is the same as a high AC input signal by receiving the high AC input signal V_{INN}; and a MUX M₁ outputting a detection result of any one of the first mode operation circuit unit and the second mode operation circuit unit, wherein any one of the first mode operation circuit unit and the second mode operation circuit unit may operate or both may not operate.

### CROSS-REFERENCE TO RELATED APPLICATION

This application claims the benefit of priority under 35 U.S.C. § 119(a) to Korean Patent Application No. 10-2024-0037826 filed on Mar. 19, 2024, the entire contents of which are incorporated herein by reference.

### BACKGROUND

### (a) Technical Field

The present disclosure relates to a hybrid comparator circuit device which may widely detect a point where an output voltage and an input voltage meet in a resonant regulating rectifier.

### (b) Background Art

Instead of a technology that supplies power to electronic devices by wire, a technology to supply power by wireless power transfer (WPT) is emerging. In a WPT system, a transmitter and a receiver send and receive power through a magnetic field change of a coil. The receiver as a 2-stage structure type consists of an AC-DC rectifier and a DC-DC converter (see FIG. 1).

The AC-DC rectifier converts an AC voltage V_{INN} into a DC voltage V_{REC}, and at this time, V_{REC} is not set to a targeted voltage value through feedback, but changes according to a distance, an angle, and a load R_{L} between coils. For this reason, the DC-DC converter is required at a rear stage, and the DC-DC converter switches an unstable DC voltage V_{REC} into a stable DC voltage V_{REG} through feedback. Moreover, the DC voltage V_{REG} is adjustable according to a target of a consumer/designer, and does not almost change according to the distance, the angle, and the load R_{L} between coils.

The system having the 2-stage structure has various disadvantages. Among them, first, there is a disadvantage in that power conversion efficiency is low, and a voltage conversion rate is low through two structures. Further, there is a disadvantage in that a chip size is large due to the 2-stage structure type.

In order to solve the problems, proposed is a resonant regulating rectifier which reduces the 2-stage structure type to a 1-stage structure type in “A Power-Efficient Wireless System With Adaptive Supply Control for Deep Brain Stimulation, JSSC, 2013”. In order to convert an AC voltage into a stable and targeted DC voltage by a 1-stage structure, a pulse width modulation (PWM) technology is applied as illustrated in FIG. 2. The PWM modulation technology decreases a pulse width when a targeted voltage is low and increases the pulse width when the targeted voltage is high.

The resonant regulating rectifier in the related art detects a point where an input AC voltage V_{INN} and an output DC voltage V_{REG} coincide with each other by using a single comparator as illustrated in FIG. 3, and has a disadvantage in that this range is limited.

### SUMMARY OF THE DISCLOSURE

The present disclosure is to provide a hybrid comparator circuit device.

The present disclosure is to provide a hybrid comparator circuit device which may widely detect a point where an output voltage and an input voltage meet in a resonant regulating rectifier, and is thus capable of converting power with a wide output voltage regulating range and high efficiency.

According to an aspect of the present disclosure, provided is a hybrid comparator circuit device.

According to an embodiment of the present disclosure, a hybrid comparator circuit device may be provided, which includes: a first mode operation circuit unit detecting a first point where a first reference signal V_{REG} is the same as a low AC input signal by receiving the low AC input signal V_{INN}; a second mode operation circuit unit detecting a second point where a second reference signal V_{REG} is the same as a high AC input signal by receiving the high AC input signal V_{INN}; and a MUX M₁ outputting a detection result of any one of the first mode operation circuit unit and the second mode operation circuit unit, wherein any one of the first mode operation circuit unit and the second mode operation circuit unit operates or both do not operate depending on a control signal.

The first mode operation circuit unit may include a first transistor N₁ of which source is connected to a first input node receiving the first reference signal V_{REG} and a second transistor N₂ of which source is connected to a second input node receiving the input signal V_{INN}, and the second mode operation circuit unit may include a third transistor P₁ of which source is connected to the first input node and a fourth transistor P₂ of which source is connected to the second input node, wherein the first transistor N₁ and the second transistor N₂ may be any one of NMOS and PMOS, and the third transistor P₁ and the fourth transistor P₂ may be the other one of NMOS and PMOS.

The low AC input signal V_{INN} may be a signal in which the reference voltage V_{REG} is equal to or smaller than an operating power (V_{DD})/2, and the high AC input signal V_{INN} may be a signal in which the reference voltage V_{REG} is larger than the operating power (V_{DD})/2.

The hybrid comparator circuit device further includes a selector circuit unit comparing an operating power and a target voltage V_{TG} to output an operation mode control signal, and the operation mode control signal is any one of a low mode control signal, a high mode control signal, and an off mode control signal.

The selector circuit unit may include an internal comparator receiving the operating power V_{DD} through a + input terminal and receiving the target voltage V_{TG} through a − input terminal, and then generating an output signal V_{A2}, a first internal MUX M₂ receiving the output signal V_{A2}, and then outputting a control signal according to a start control signal Φ_{STR}, a second internal MUX M₃ inverting and receiving the control output by the first internal MUX M₂, and then outputting a high control signal S_{H} according to the start control signal Φ_{STR}; and a third internal MUX M₄ inverting and receiving the inverted control signal again, and then outputting a low control signal S_{L} according to the start control signal Φ_{STR}, wherein the inverted control signal may be input as a control signal for selecting the output of the MUX M₁ into the MUX, and the MUX M₁ may selectively output a detection result of any one of the first mode operation circuit unit and the second mode operation circuit unit according to the inverted control signal.

A hybrid comparator circuit device according to an embodiment of the present disclosure is provided to widely detect a point where an output voltage and an input voltage meet in a resonant regulating rectifier, and to be thus capable of converting power with a wide output voltage regulating range and high efficiency.

### BRIEF DESCRIPTION OF THE DRAWINGS

FIGS. 1 to 3 are diagrams illustrating the related art.

FIG. 4 is a diagram illustrating a hybrid comparator circuit device according to an embodiment of the present disclosure.

FIG. 5 is a detailed circuit diagram of a hybrid comparator circuit unit of FIG. 4.

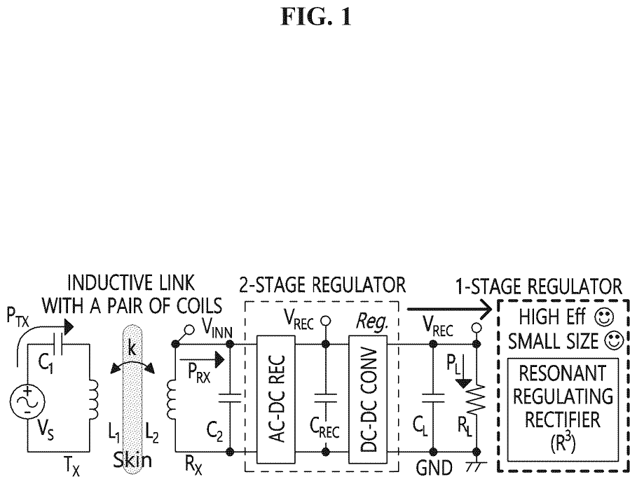

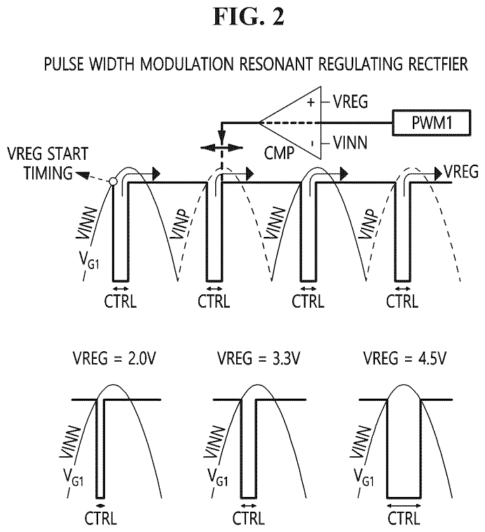

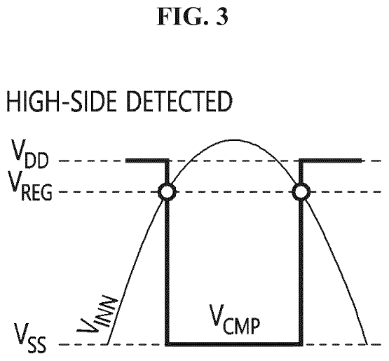

### DETAILED DESCRIPTION

A singular form used in this specification includes a plural form unless the context clearly dictates otherwise. In this specification, a term such as “comprising” or “including” should not be construed as necessarily including all various components or various steps disclosed in this specification, and it should be construed that some component or some steps among them may not be included or additional components or steps may be further included. In addition, the terms including “unit’, “module”, and the like disclosed in this specification mean a unit that processes at least one function or operation and this may be implemented by hardware or software or a combination of hardware and software.

Hereinafter, the embodiment of the present disclosure will be described in detail with reference to the accompanying drawings.

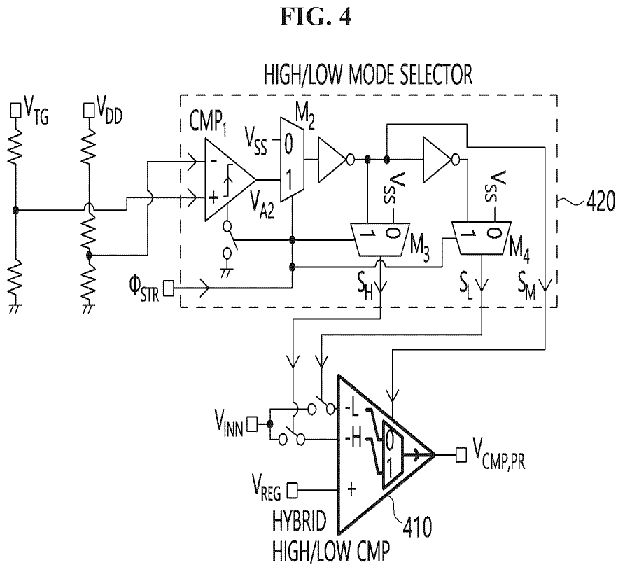

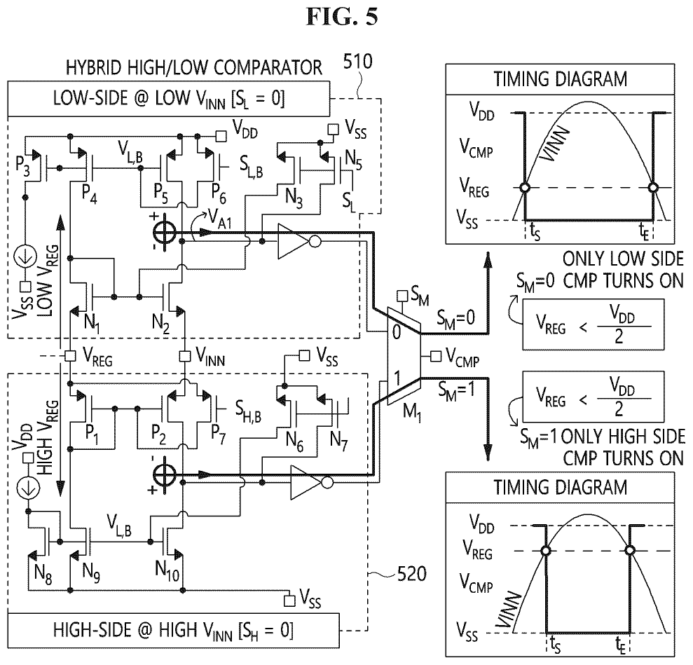

FIG. 4 is a diagram illustrating a detailed configuration of a hybrid comparator circuit device in a resonant regulating rectifier according to an embodiment of the present disclosure.

Referring to FIG. 4, the hybrid comparator circuit device according to an embodiment of the present disclosure is configured to include a hybrid comparator circuit unit 410 and a selector circuit unit 420.

The hybrid comparator circuit unit 410 is a means for detecting a point where a reference signal V_{REG} is the same by selectively receiving any one of a low AC input signal V_{INN} and a high AC input signal V_{INN}.

The hybrid comparator circuit unit 410 according to an embodiment of the present disclosure is configured to include a first mode operation circuit unit 510, a second mode operation circuit unit 520, and a MUX M₁.

Any one of the first mode operation circuit unit 510 and the second mode operation circuit unit 520 may selectively operate, and receive the input signal V_{INN} to output a result of detecting a point where the reference signal V_{REG} is the same. Hereinafter, the reference signals V_{REG} input into the first mode operation circuit unit 510 and the second mode operation circuit unit 520 may be different. That is, the first mode operation circuit unit 510 detects a first point where a low AC input signal V_{INN} coincides with a reference voltage V_{REG} smaller than an operating power (V_{DD})/2, and may operate when both the reference voltage V_{REG} and the AC input signal V_{INN} are equal to or smaller than the operating power (V_{DD})/2.

On the contrary, the second mode operation circuit unit 520 detects a second point where a high AC input signal V_{INN} coincides with a reference voltage V_{REG} larger than the operating power (V_{DD})/2, and may operate when both the reference voltage V_{REG} and the AC input signal V_{INN} are larger than the operating power (V_{DD})/2.

The hybrid comparator circuit unit 410 may include a first mode (hereinafter referred to as low mode) in which the first mode operation circuit unit 510 operates, a second mode (hereinafter referred to as high mode) in which the second mode operation circuit unit 520 operates, and an off mode (a mode in which the first mode operation circuit unit 510 and the second mode operation circuit unit 520 do not operate).

The hybrid comparator circuit unit 410 may operate in any one of the first mode (low mode), the second mode (high mode), and the off mode according to the operation mode control signal output by the selector circuit unit 420.

In this specification, the first mode (low mode) is a mode which operates by receiving the low AC input signal V_{INN}, and the low AC input signal V_{INN} will be defined as an AC input signal in which the reference voltage V_{REG} is equal to or smaller than the operating power (V_{DD})/2.

Further, the second mode (high mode) is a mode which operates by receiving the high AC input signal V_{INN}, and the high AC input signal V_{INN} will be defined as an AC input signal in which the reference voltage V_{REG} is larger than the operating power (V_{DD})/2.

This will be appreciated more clearly by the following description.

The first mode operation circuit unit 510 may detect the first point where the reference signal V_{REG} is the same as the low AC input signal by receiving the low AC input signal V_{INN} to output a detection result.

The first mode operation circuit unit 510 may receive the reference signal V_{REG} and the low AC input signal V_{INN} through a first transistor N₁ and a second transistor N₂. That is, a source of the first transistor N₁ may be connected to a first input node receiving the reference signal V_{REG}, and a source of the second transistor N₂ may be connected to a second input node receiving the input signal V_{INN}. Further, a gate of the first transistor N₁ may be connected to a gate of the second transistor N₂.

A drain of the first transistor N₁ may be connected to a drain of a transistor P₄, and a source of the transistor P₄ may be connected to an input node of an operating power supply V_{DD}.

Further, the gate of the second transistor N₂ may be connected to a low mode switch N₃ at a contact where the gate of the second transistor N₂ is connected to the gate of the first transistor N₁. The low mode switch N₃ may be an NMOS transistor, and the gate may be connected to an input node which inputs a mode control signal. Further, a drain of the low mode switch N₃ may be connected at a contact node where the gate of the second transistor N₂ is connected to the gate of the first transistor N₁.

Further, a drain of the second transistor N₂ may be connected to a drain of a transistor P₅. A source of the transistor P₅ may be connected to an input node of the operating power supply V_{DD}. Further, a gate of the transistor P₅ may be connected to gates of a transistor P₄ and the transistor P₃. At this time, a contact node where the gate of the transistor P₅ and the gate of the transistor P₄ are connected may be connected to a drain of a transistor P₆. A source of the transistor P₆ may be connected to the input node of the operating power supply V_{DD}, and the gate may be connected to an input node S_{L} receiving the low mode control signal.

The first mode operation circuit unit 510 detects a point where the low mode control signal S_{L} is received through the gate of the low mode switch N₃, and the first transistor N₁ and the second transistor N₂ are turned on according to the corresponding low mode control signal S_{L}, and the reference signal V_{REG} and the input signal V_{INN} are input, and then the reference signal V_{REG} and the input signal V_{INN} are equal to each other to output a detection result.

The second mode operation circuit unit 520 may receive the reference signal V_{REG} and the low AC input signal V_{INN} through a third transistor P₁ and a fourth transistor P₂. That is, a source of the third transistor P₁ may be connected to the first input node receiving the reference signal V_{REG} and a source of the fourth transistor P₂ may be connected to the second input node receiving the input signal V_{INN}. Further, a gate of the third transistor P₁ may be connected to a gate of the fourth transistor P₂.

Further, a contact node where the gate of the third transistor P₁ and the gate of the fourth transistor P₂ are connected may be connected to a contact node where a drain of the third transistor P₁ and a drain of a transistor N₉ are connected. Further, a contact node where the gate of the fourth transistor P₂ is connected may be connected to a drain of a transistor P₇. A source of the transistor P₇ may be connected to the first input node receiving the reference signal V_{REG} and a contact node with the source of the third transistor P₁, and a high mode control signal S_{H} may be applied to the gate.

A drain of the fourth transistor P₂ may be connected to a drain of a transistor N₁₀, and a source of the transistor N₁₀ may be connected to an input power supply V_{SS}, and a gate may be connected to a drain of a high mode switch N₆. The high mode control signal S_{H} may be applied to a gate of the high mode switch N₆. A source of the high mode switch N₆ may be connected to the input power supply V_{SS}.

The second mode operation circuit unit 520 detects a second point where the high mode control signal S_{H} is received through the gate of the low mode switch N₆, and the third transistor P₁ and the fourth transistor P₂ are turned on according to the corresponding high mode control signal S_{H}, and the reference signal V_{REG} and the input signal V_{INN} are input, and then the reference signal V_{REG} and the high AC input signal V_{INN} are equal to each other to output a detection result. The reference signals V_{REG} applied to the first mode operation circuit unit 510 and the second mode operation circuit unit 520 may also be different from each other.

The MUX M₁ may selectively output the detection results of the first mode operation circuit unit 510 and the second mode operation circuit unit 520 according to a control signal.

That is, the hybrid comparator circuit unit 410 may receive the low AC input signal V_{INN} through the first mode operation circuit unit 510, and receive the high AC input signal V_{INN} through the second mode operation circuit unit 520 according to the control signal output by the selector circuit unit 420.

The selector circuit unit 420 may compare an operating power and a target voltage V_{TG} to output an operation mode control signal. For example, the selector circuit unit 420 may output any one of a low mode control signal, a high mode control signal, and an off mode control signal as the operation mode control signal.

When the hybrid comparator circuit unit 410 operates in the low mode, the selector circuit unit 420 may output the low mode control signal as 0, and output the high mode control signal as 1, and a selection control signal may be output as 0 so that the MUX M₁ outputs the detection result of the first mode operation circuit unit 510.

On the contrary, when the hybrid comparator circuit unit 410 operates in the high mode, the selector circuit unit 420 may output the high mode control signal as 1, and output the high mode control signal as 0, and the selection control signal may be output as 1 so that the MUX M₁ outputs the detection result of the second mode operation circuit unit 520.

Further, when the hybrid comparator circuit unit 410 operates in the off mode, the selector circuit unit 420 may output each of the low mode control signal and the high mode control signal as 1.

A detailed structure of the selector circuit unit 420 will be described in more detail.

The selector circuit unit 420 is configured to include an internal comparator CMP₁, a second MUX M₂, a third MUX M₃, and a fourth MUX M₄.

The internal comparator CMP₁ may receive the operating power V_{DD} through a + input terminal, and receive the target voltage V_{TG} through a − input terminal, and then generate an output signal V_{A2}. The internal comparator CMP₁ may compare V_{DD}/2 and the target voltage V_{TG} to generate the output signal V_{A2}. The output signal V_{A2} of the internal comparator CMP₁ may be transferred to the second MUX M₂.

The second MUX M₂ may receive the output signal V_{A2} of the internal comparator CMP₁, and then output the control signal according to a start control signal Φ_{STR}. The control signal output by the second MUX M₂ may be inverted through a NOT gate, and input into the third MUX M₃. The corresponding inverted control signal may be inverted through the NOT gate again, and input into a fourth MUX M₄. The third MUX M₃ may receive the inverted control signal (i.e., a signal inverted once), and then output the high control signal S_{H} according to the start control signal Φ_{STR}.

Further, the inverted control signal may be inverted again, and input into the fourth MUX M₄. The fourth MUX M₄ may receive a signal (i.e., a signal inverted twice) acquired by inverting the inverted control signal again, and then output the low control signal S_{L} according to the start control signal Φ_{STR}.

Further, the inverted control signal may be input into the MUX M₁ as the selection control signal which selects the output of the MUX M₁. The MUX M₁ inside the hybrid comparator circuit unit 410 may selectively output the detection result of any one of the first mode operation circuit unit 510 and the second mode operation circuit unit 520 according to the corresponding inverted control signal.

Outputs of the high mode control signal S_{H}, the low mode control signal S_{L}, and the selection control signal S_{M} may be determined by the output signal V_{A2} of the comparator CMP₁, and the start control signal Φ_{STR}.

In summary, when the low mode control signal S_{L}, the high mode control signal S_{H}, and the selection control signal S_{M} are 0, 1, and 0, respectively, the hybrid comparator circuit unit may operate in the low mode, and when the low mode control signal S_{L}, the high mode control signal S_{H}, and the selection control signal S_{M} are 1, 0, and 1, respectively, the hybrid comparator circuit unit may operate in the high mode. In addition, when the low mode control signal S_{L}, the high mode control signal S_{H}, and the selection control signal S_{M} are 1, 1, and n/a, respectively, the hybrid comparator circuit unit 410 may operate in the off mode.

When the reference voltage V_{REG} is equal to or smaller than the operating power (V_{DD})/2, 0 is output as the selection control signal, and the hybrid comparator circuit unit 410 may operate in the low mode to receive the reference signal and the input signal through the first mode operation circuit unit 510.

On the contrary, when the reference voltage V_{REG} is larger than the operating power (V_{DD})/2, 1 is output as the selection control signal, and the hybrid comparator circuit unit 410 operates in the high mode to receive the reference signal and the input signal through the second mode operation circuit unit 520.

As described above, the hybrid comparator circuit device can widely detect a point where an output voltage and an input voltage meet in a resonant regulating rectifier, and is thus capable of converting power with a wide output voltage regulating range and high efficiency.

The present disclosure has been described above with reference to the embodiments thereof. It will be understood to those skilled in the art that the present disclosure may be implemented as a modified form without departing from an essential characteristic of the present disclosure. Therefore, the disclosed embodiments should be considered in an illustrative viewpoint rather than a restrictive viewpoint. The scope of the present disclosure is defined by the appended claims rather than by the foregoing description, and all differences within the scope of equivalents thereof should be construed as being included in the present disclosure.

What is claimed is:

1. A hybrid comparator circuit device, comprising:
a first mode operation circuit unit detecting a first point where a first reference signal V_{REG} is the same as a low AC input signal by receiving the low AC input signal V_{INN};
a second mode operation circuit unit detecting a second point where a second reference signal V_{REG} is the same as a high AC input signal by receiving the high AC input signal V_{INN}; and
a MUX M₁ outputting a detection result of any one of the first mode operation circuit unit and the second mode operation circuit unit,
wherein any one of the first mode operation circuit unit and the second mode operation circuit unit operates or both do not operate.

2. The hybrid comparator circuit device of claim 1, wherein the first mode operation circuit unit includes a first transistor N₁ of which source is connected to a first input node receiving the first reference signal V_{REG} and a second transistor N₂ of which source is connected to a second input node receiving the input signal V_{INN}, and
the second mode operation circuit unit includes a third transistor P₁ of which source is connected to the first input node and a fourth transistor P₂ of which source is connected to the second input node,
wherein the first transistor N₁ and the second transistor N₂ are any one of NMOS and PMOS, and
the third transistor P₁ and the fourth transistor P₂ are the other one of NMOS and PMOS.

3. The hybrid comparator circuit device of claim 1, wherein the low AC input signal V_{INN} is a signal in which the reference voltage V_{REG} is equal to or smaller than an operating power (V_{DD})/2, and
the high AC input signal V_{INN} is a signal in which the reference voltage V_{REG} is larger than the operating power (V_{DD})/2.

4. The hybrid comparator circuit device of claim 2, further comprising:
a selector circuit unit comparing an operating power and a target voltage V_{TG} to output an operation mode control signal,
wherein the operation mode control signal is any one of a low mode control signal, a high mode control signal, and an off mode control signal.

5. The hybrid comparator circuit device of claim 4, wherein the selector circuit unit includes
an internal comparator receiving the operating power V_{DD} through a + input terminal and receiving the target voltage V_{TG} through a − input terminal, and then generating an output signal V_{A2},
a first internal MUX M₂ receiving the output signal V_{A2}, and then outputting a control signal according to a start control signal Φ_{STR};
a second internal MUX M₃ inverting and receiving a control signal output by the first internal MUX M₂, and then outputting a high control signal S_{H} according to the start control signal Φ_{STR}; and
a third internal MUX M₄ inverting and receiving the inverted control signal again, and then a low control signal S_{L} according to the start control signal Φ_{STR},
wherein the inverted control signal is input as a control signal for selecting the output of the MUX M₁ into the MUX, and
the MUX M₁ selectively outputs a detection result of any one of the first mode operation circuit unit and the second mode operation circuit unit according to the inverted control signal.
